(19) United States
(12) Patent Application Publication
(10) Pub. No.: US 2006/0073704 A1
(43) Pub. Date: Apr. 6, 2006

(54) Method of forming bump that may reduce possibility of losing contact pad material

(76) Inventors: Se-young Jeong, Seoul (KR); In-young Lee, Yongin-si (KR); Sung-min Sim, Seongnam-si (KR); Young-hee Song, Seongnam-si (KR); Dong-hyeon Jang, Suwon-si (KR); Myeong-soon Park, Suwon-si (KR); Sun-young Park, Iksan-si (KR); Sun-bum Kim, Hwaseong-si (KR); Hyun-soo Chung, Hwaseong-si (KR)

Correspondence Address: HARNESS, DICKEY & PIERCE, P.L.C., P.O. BOX 8910, RESTON, VA, 20195, US

(21) Appl. No.: 11/210,817

(22) Filed: Aug. 25, 2005

(30) Foreign Application Priority Data
Aug. 25, 2004 (KR) 2004-67094
Aug. 25, 2005 (KR) 10-2004-0078094

(51) Int. Cl. H01L 21/302; H01L 21/461; B44C 1/22

(52) U.S. Cl. 438/706; 216/58; 216/41

(57) ABSTRACT

A method of forming a bump may involve providing a seed layer on a contact pad of a wafer. A shielding layer and a photosensitive mask layer may be formed on the seed layer. The photosensitive mask layer may be exposed and developed to form a mask pattern. An exposed portion of the shielding layer may be removed. The bump may be formed by plating the exposed seed layer.

### CROSS-REFERENCE TO RELATED APPLICATIONS

This application claims the priority of Korean Patent Application No. 2004-67094, filed on Aug. 25, 2004, in the Korean Intellectual Property Office, the disclosure of which is incorporated herein in its entirety by reference.

### BACKGROUND OF THE INVENTION

1. Field of the Invention

The present invention relates in general to packaging of semiconductor devices, and more particularly to a method of forming a bump on a contact pad of a wafer that may reduce loss of the contact pad material.

2. Description of the Related Art

Electrical testing of semiconductor devices or integrated circuits that are formed on a wafer may be carried out before packaging the semiconductor devices. A contact pad formed on a wafer may have a surface exposed through a passivation layer. A probe may come into contact with the surface of the contact pad to conduct electrical testing, and this may form a probe mark on the contact pad.

The probe mark on the contact pad may produce an undesired topology on the surface of the contact pad, which may result in a failure during a bump forming process. When a probe tip contacts the contact pad, a surface of the contact pad may be pushed backward or distorted, which may generate a dent and/or an overhang figuration. Such topology may be a factor that leads to exposing the contact pad to chemical solutions (for example) that may be used during a bump forming process.

FIG. 1 is a sectional view schematically illustrating the damage to the contact pad that may occur during a conventional bump forming process.

Referring to FIG. 1, the conventional bump forming process may involve forming a contact pad 20 on a wafer 10. A first and/or a second passivation layers 31 and 35 may be formed through which the contact pad 20 may be exposed. Electrical testing may be performed during which a probe tip may contact an exposed surface of the contact pad 20. A probe mark 25 may be left on the surface of the contact pad 20 as a result of the contact between the probe tip and the contact pad 20.

To form a bump (such as a solder bump) on the exposed contact pad 20, a seed layer 40 for a deposition process (such as an electroplating process, for example) may be formed to cover the portion of the contact pad 20 exposed through the passivation layers 31 and 35. The seed layer 40 may be formed on the entire surface of the wafer 10. The seed layer 40 may include a conductive layer and/or a metal layer. The seed layer 40 may be formed by a deposition process, such as sputtering, for example.

The probe mark 25, which may be formed in the contact pad 20, may hinder sputtering of a seed layer 40 that uniformly covers the surface of the contact pad 20. Accordingly, the seed layer 40 may have an uneven thickness, a local crevice, a crack, and/or some other defects because of the probe mark 25 and the resulting topology of the contact pad 20. Such defects may result in a portion of the contact pad 20 being exposed through the seed layer 40, as shown in FIG. 1.

A mask pattern 50, for selectively forming a bump on the seed layer 40, may be formed on the wafer 10. For example, a photoresist layer may be provided on the seed layer 40. The photoresist layer may be exposed and developed, thereby forming the mask pattern 50.

If the seed layer 40 has defects, then the underlying contact pad 20 may be susceptible to damage. For example, chemical solutions 55 (which may be introduced to etch and develop the photoresist layer to form the mask pattern 50) may inadvertently permeate through the seed layer 40 and touch the contact pad. In this way, the chemical solutions 55 may erode the contact pad 20. The chemical solutions 55 (or developer) may contain base components (such as TMAH, NaOH or KOH, for example) that may react with a constituent component of the contact pad 20. For example, the contact pad 20 may include aluminum as a constituent component. The developer base components may react with the aluminum of the contact pad 20, resulting in dissolution of the aluminum.

The dissolution of the aluminum component causes an undesired loss of the material of the contact pad 20, which in turn may produce a vacant space (or void) in the contact pad 20. The vacant space may inhibit (among other things) a stable electrical and/or a mechanical connection of the subsequently formed bump to the wafer 10. The loss of the material of the contact pad 20 may result in a connection failure, such as a flip chip connection failure, for example.

### SUMMARY OF THE INVENTION

According to an example, non-limiting aspect of the present invention, a method of forming a bump may involve preparing a wafer having a contact pad. A seed layer that covers the contact pad may be formed. A shielding layer may be formed on the seed layer. A photosensitive mask layer may be formed on the shielding layer. The mask layer may be exposed and developed to form a mask pattern that exposes a portion of the shielding layer. The exposed portion of the shielding layer may be removed by dry etching using the mask pattern as an etch mask. The bump may be formed by plating the seed layer exposed by the dry etching.

According to another example, non-limiting embodiment of the present invention, a method of forming a bump may involve providing a wafer having a contact pad. A seed layer may be provided on the contact pad. A shielding layer may be provided on the seed layer. A mask pattern may be provided on the shielding layer. A portion of the shielding layer exposed through the mask pattern may be removed. And the bump may be formed on the seed layer.

### BRIEF DESCRIPTION OF THE DRAWINGS

The above and other features of the present invention will become more apparent by describing in detail example, non-limiting embodiments thereof with reference to the attached drawings in which:

FIG. 1 is a sectional view schematically showing a loss of the material of a contact pad when conventionally forming bumps on a wafer.

FIG. 2 is a sectional view of a probe mark on a contact pad according to an example embodiment of the present invention.

FIG. 3 is a sectional view of a seed layer according to an example embodiment of the present invention.

FIG. 4 is a sectional view of a shielding layer according to an example embodiment of the present invention.

FIG. 5 is a sectional view of a mask layer according to an example embodiment of the present invention.

FIG. 6 is a sectional view of a mask pattern according an example embodiment of the present invention.

FIG. 7 is a sectional view of a shielding layer pattern according to an example embodiment of the present invention.

FIG. 8 is a sectional view of a first plating layer according to an example embodiment of the present invention.

FIG. 9 is a sectional view of a second plating layer according to an example embodiment of the present invention.

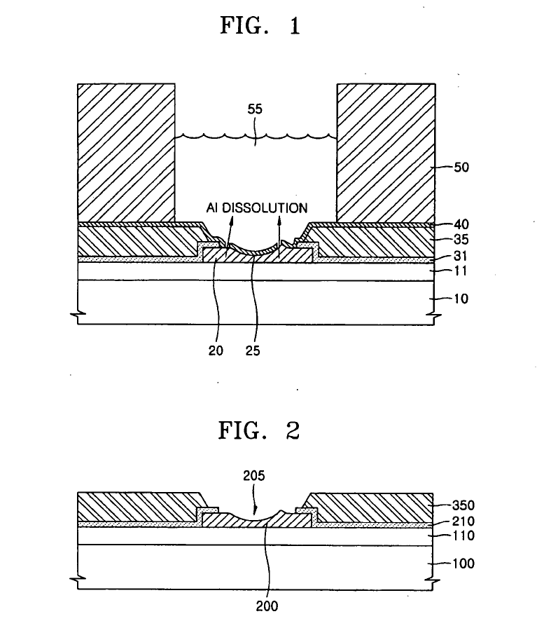

### DETAILED DESCRIPTION OF EXEMPLARY EMBODIMENTS OF THE INVENTION

Example, non-limiting embodiments of the present invention will now be described more fully with reference to the accompanying drawings. The invention may, however, be embodied in many different forms and should not be construed as being limited to the embodiments set forth herein; rather these embodiments are provided so that this disclosure will be thorough and complete, and will fully convey the concept of the invention to those skilled in the art.

The Figures are intended to illustrate the general characteristics of example, non-limiting embodiments of the invention. The drawings are not, however, to scale and may not precisely reflect the characteristics of any given embodiment, and should not be interpreted as defining or limiting the range of values or properties of example embodiments within the scope of this invention. The relative thicknesses and positioning of layers or regions may be reduced or exaggerated for clarity. Further, a layer is considered as being formed “on” another layer or a substrate when formed either directly on the referenced layer or the substrate or formed on other layers or patterns overlaying the referenced layer.

In an example, non-limiting embodiment of the present invention, a contact pad on a wafer may be effectively shielded to reduce (for example) the possibility of the contact pad being eroded or dissolved by chemical solutions, such as a developer that may be introduced during a bump forming process. To this end, a shielding layer may be formed on the contact pad. The shielding layer may be patterned via dry etching (for example) so that the underlying contact pad may be selectively exposed.

FIGS. 2 through 9 are sectional views diagrammatically illustrating a bump forming process according to an example, non-limiting embodiment of the present invention.

FIG. 2 illustrates a wafer 100 with a contact pad 200 having a probe mark 205.

Referring to FIG. 2, the contact pad 200 may be disposed on the wafer 100, which may be packed with integrated circuit (IC) devices or semiconductor devices An insulating layer 110 may be interposed between the contact pad 200 and the wafer 100. The contact pad 200 may be electrically connected to the underlying IC devices or the semiconductor devices via connectors (not illustrated) that penetrate through the insulating layer 110.

The wafer 100 may be covered with passivation layers 210 and 350 that may be a single layer or multiple layers. It will be appreciated that the invention is not limited to any specific number of passivation layers. When the passivation layer is formed of multiple layers, as shown in FIG. 2, the first passivation layer 210 may be composed of an insulating material such as Si₃N₄, for example. And a second passivation layer 350 may be composed of a polymer having an insulating property, such as polyimide, for example. The passivation layers may be fabricated from numerous other alternative materials, as is well known in this art, and therefore a detailed description of the same is omitted. The first passivation layer 210 may expose an upper surface of the contact pad 200, and the second passivation layer 350 may cover a fuse placed (not illustrated) on the wafer 100.

A probe tip may contact the exposed surface of the contact pad 200 to carry out electrical testing. During the electrical testing, a probe mark 205 is accompanied in the surface of the contact pad 200 caused by the contact with the probe tip.

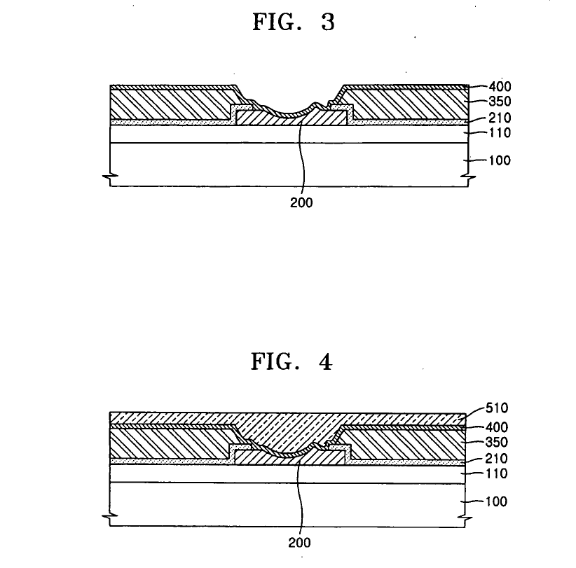

FIG. 3 illustrates a seed layer 400 on which a bump may be formed. In this example embodiment, the bump may be formed via a deposition technique, such as electroplating, for example.

Referring to FIG. 3, the seed layer 400 may extend over the passivation layers 210 and 350 and the contact pad 200. As noted above, the seed layer 400 in this example embodiment may be a plating seed layer for plating bumps.

The seed layer 400 may be composed of a metal that is selected based on a material of the bump that will be formed on the seed layer 400. For example, if a solder bump is to be formed, then the seed layer 400 may include a Ni layer. Here, a Ti layer may be provided below the Ni layer to increase an adhesive property. If a Cu bump is to be formed, then the seed layer 400 may include a Cu layer. Numerous and varied materials may be suitably implemented to form the seed layer 400 and the bump, as is well known in this art, and therefore a detailed discussion of the same is omitted. By way of example only, and not as a limitation of the invention, the seed layer 400 may be formed by a deposition technique, such as sputtering, for example.

The probe mark 205 on the contact pad 200 may cause the seed layer 400 to inconsistently extend over the surface of the contact pad 200. In other words, the varied topology of the contact pad (which may be caused by the bottom of the probe mark 205 and the surrounding overhang, etc.) may make the seed layer 400 have an irregular and uneven thickness. Thus, the seed layer 400 may not effectively shield the contact pad 200 during subsequent processing. That is, the seed layer 400 may have a gap and/or crevice through which a portion of the contact pad 200 may be exposed.

To compensate for possible exposure of the contact pad 200 through the seed layer 400, a shielding layer may be provided on the seed layer 400. The shielding layer may fill the gap or crevice in the seed layer 400.

FIG. 4 illustrates a shielding layer 510 that may be provided on the seed layer 400. [0038] Referring to FIG. 4, the shielding layer 510 may cover the seed layer 400. The shielding layer 510 may be fabricated from a material that is selected in view of materials that may be employed during subsequent processing. For example, the shielding layer material may be selected to resist the chemical solutions that may be used for developing (e.g., chemically etching, dissolving, etc.) a photoresist. Also, the shielding layer 510 may be fabricated from a material that can be patterned by dry etching.

By way of example only, and not as a limitation of the invention, the shielding layer 510 may be fabricated from a polymer material with non-conductivity. Such materials may include, but are not limited to, a positive photoresist material, a negative photoresist material, a photosensitive polyimide, and/or a non-photosensitive polyimide. The polymer layer may be provided via coating techniques that are well known in this art.

In this example embodiment, the shielding layer 510 may be fabricated from a material that resists removal by a developer that may be introduced to pattern a mask pattern, as discussed in more detail below. A thickness of the shielding layer 510 may be set by considering a thickness of the mask pattern, which may be approximately 0.1 μm to 10 μm, for example. It will be appreciated that the thicknesses of the shielding layer 510 and the mask pattern may be varied without departing from the spirit and scope of the present invention.

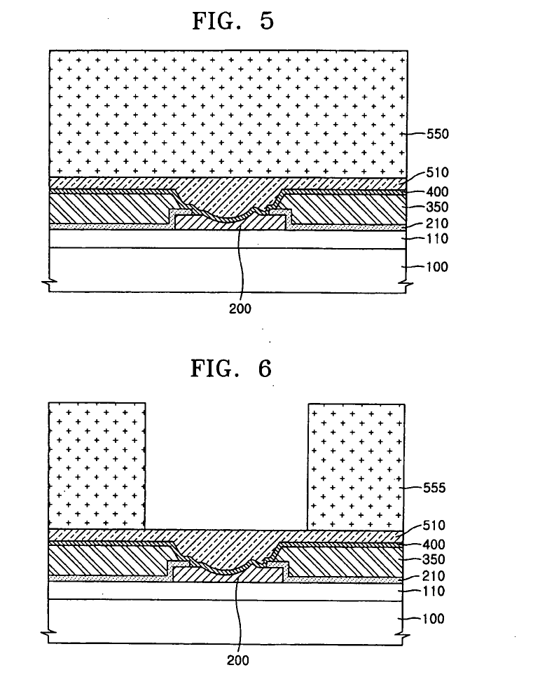

FIG. 5 illustrates a mask layer 550 that may be provided on the shielding layer 510.

Referring to FIG. 5, the mask layer 550 may be provided on the shielding layer 510 via coating techniques that are well known in this art. The mask layer 550 may be fabricated from a photosensitive polymer material, for example.

By way of example only, and not as a limitation of the invention, the polymer material of the mask layer 550 may include a positive photoresist material, a negative photoresist material or a photosensitive polyimide. The material of the mask layer 550 may differ from the material of the underlying shielding layer 510.

Consider a scenario in which the mask layer 550 is fabricated from a photosensitive polymer. Here, the underlying shielding layer 510 may be fabricated from a non-photosensitive material, such as a non-photosensitive polyimide for example. Alternatively, the shielding layer 510 may be fabricated from a polymer having an opposite exposure reaction as compared to that of the photosensitive polymer of the mask layer 550. For example, when the mask layer 550 is fabricated from a negative photoresist, then the shielding layer 510 may be fabricated from a positive photoresist, a photosensitive polyimide, etc.

FIG. 6 illustrates a mask pattern 555.

Referring to FIG. 6, the mask layer 550 may be exposed and developed, thereby forming the mask pattern 555 that selectively exposes the surface of the shielding layer 510. At this time, the mask pattern 555 may be formed to have opening corresponding to the surface of the contact pad 200.

For example, assume that the mask layer 550 is formed by coating a negative photoresist. A negative mask may be used for performing exposure and the mask pattern 555 may be formed by developing. Here, the shielding layer may be fabricated from a non-photosensitive polymer or a photosensitive polymer having an opposite exposure reaction, e.g., a positive photoresist. Accordingly, the shielding layer 510 may not be developed (e.g., chemically etched, dissolved, etc.) by the exposure and development of the mask pattern 555. This is because the portions of the shielding layer 510 that may be exposed to exposing radiation (and thus may become more sensitive to the developer) may remain covered by the mask pattern 555, while the portions of the shielding layer 510 that may not be exposed to exposing radiation may remain resistant to the developer. Accordingly, the shielding layer 510 may not be developed, but instead remains substantially in tact to effectively protect and shield the underlying contact pad 200. As a result, the developer may not reach the contact pad 200, thereby preventing a loss of the contact pad 200 caused by the developer.

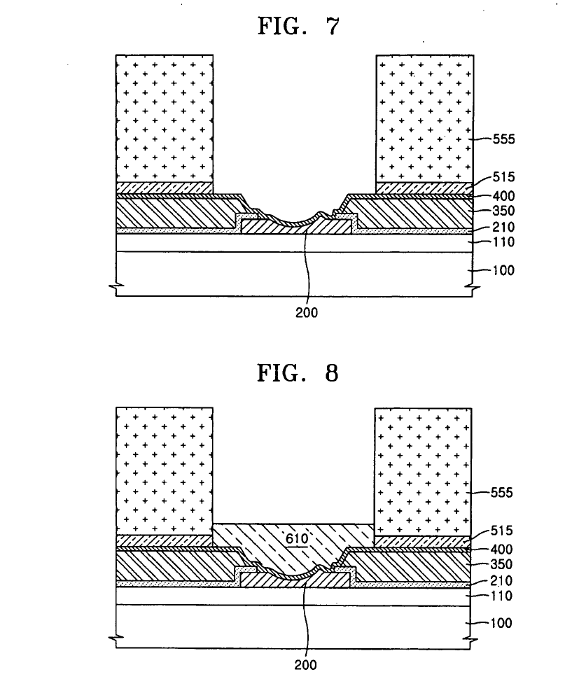

FIG. 7 illustrates a shielding layer pattern 515.

Referring to FIG. 7, the shielding layer pattern 515 may formed by removing portions of the shielding layer 510. The portions of the shielding layer 510 may be removed, for example, via dry etching techniques that are well known in this art. The shielding layer 510 may be dry etched using the mask pattern 555. The dry etching may be (for example) plasma etching using an etchant including O₂ gas and/or a carbon fluoride-based gas such as CF4. The etchant may further include N₂ gas and/or Ar gas. By doing so, a portion of the seed layer 400 (which may correspond to the underlying contact pad 200) may be selectively etched and exposed through the mask pattern 555. Numerous and varied etchant gases, which are well known in this art, may be suitably implemented without departing from the scope of the invention. It will also be appreciated that the shielding layer 510 may be patterned via alternative techniques, other than dry etching, that are well known in this art.

In this example embodiment, both the shielding layer pattern 515 and the mask pattern 555 may be used as a bump forming mask. Accordingly, respective thicknesses of the shielding layer 510 and the mask layer 550 may be determined by considering a total thickness of desired bump forming mask.

FIG. 8 illustrates a first plating layer 610.

Referring to FIG. 8, the first plating layer 610 may be provided on the seed layer 400. In this example embodiment, the first plating layer 610 may be grown from the portion of the seed layer 400 exposed through the mask pattern 555 and the shielding layer pattern 515 via an electroplating technique. The invention is not, however, limited to electro-plating as other deposition techniques, which are well known in this art, may be suitably implemented. The first plating layer 610 may be introduced to improve, for example, a plating feature and/or a contact feature of a second plating layer. For example, when the second plating layer is a solder plating layer for a solder bump, the first plating layer 610 may be a Ni layer that may have a thickness of about 3 μm, for example. It will be appreciated that the first plating layer 610 may be fabricated from numerous and varied materials that are well known in this art.

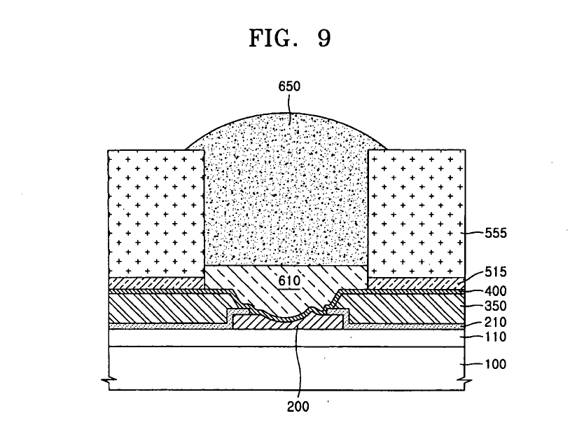

FIG. 9 illustrates a second plating layer 650.

Referring to FIG. 9, the second plating layer 650 may be formed on the first plating layer 610. The second plating layer may be formed via solder plating techniques that are well known in this art. In this example embodiment, the first plating layer 610 and the second plating layer 650 may form a bump that may serve to mechanically and/or electrically connect the wafer 100 to other devices. It will-be appreciated that the invention is not limited to a bump having two layers fabricated from different materials. For example, the two plating layers 610 and 650 may be formed via Cu bump forming techniques. Furthermore, the invention is not limited to two plating layers, since any number of plating layers (inclusive of a single plating layer) may be suitably implemented

The mask pattern 555 and the shielding layer pattern 515 may be removed. In this example embodiment, the two patterns 555 and 515 may be removed via wet etching and/or dry etching techniques that are well known in this art. The bumps 610 and 650 remaining on the wafer 100 may be used as an etch mask, so that the exposed portion of the seed layer 400 may be selectively removed. As described above, the bumps 610 and 650 may be effectively formed without damaging the underlying contact pad 200. For example, chemical solutions, which may have base components such as TMAH, NaOH or KOH, and which may be used to develop the mask pattern 555, may be inhibited from reaching the contact pad 200 (which may be fabrication from aluminium, for example) via the shielding layer 510. Accordingly, the shielding layer 510 may effectively reduce the dissolution or loss of the contact pad 200 due to the developer. Therefore, the likelihood of a failure of a bump connection (e.g., a flip chip connection) may be effectively reduced.

As described above, the shielding layer may be provided, and a photoresist layer (which may be provided on the shielding layer) may be developed using a liquid developer. A portion of the shielding layer may be dry etched to expose the underlying contact pad. In this way, the likelihood of an intrusion of chemical solutions through a seed layer may be effectively reduced.

While the present invention has been particularly shown and described with reference to exemplary embodiments, it will be understood by those of ordinary skill in the art that various changes in form and details may be made without departing from the spirit and scope of the present invention as defined by the following claims.

What is claimed is:

1. A method of forming a bump comprising:
preparing a wafer having a contact pad;
forming a seed layer that covers the contact pad;
forming a shielding layer on the seed layer;
forming a photosensitive mask layer on the shielding layer;
exposing and developing the mask layer to form a mask pattern that exposes a portion of the shielding layer;
removing the exposed portion of the shielding layer by dry etching using the mask pattern as an etch mask; and
forming the bump by plating the seed layer exposed by the dry etching.

2. The method of claim 1, wherein the shielding layer includes a non-photosensitive polymer layer.

3. The method of claim 2, wherein the photosensitive mask layer includes a positive photoresist layer, a negative photoresist layer or a photosensitive polyimide layer formed on the shielding layer.

4. The method of claim 2, wherein the shielding layer includes a non-photosensitive polyimide layer.

5. The method of claim 1, wherein the shielding layer includes a photosensitive polymer.

6. The method of claim 5, wherein the shielding layer includes a photosensitive polymer having an exposure reaction that is opposite to that of the photosensitive mask layer.

7. The method of claim 6, wherein the shielding layer includes a positive photoresist, a negative photoresist or a photosensitive polyimide.

8. The method of claim 6, wherein the photosensitive mask layer includes a positive photoresist, a negative photoresist or a photosensitive polyimide.

9. The method of claim 1, wherein the contact pad includes an aluminum layer.

10. The method of claim 1, further comprising forming a passivation layer on the wafer for exposing a surface of the contact pad.

11. The method of claim 1, wherein the seed layer includes a Ti layer and a Ni layer.

12. The method of claim 1, wherein the forming the bump comprises:
plating an Ni layer on the seed layer; and
plating a solder layer on the Ni layer.

13. The method of claim 1, comprising forming the seed layer via sputtering.

14. The method of claim 1, wherein the bump is for making a flip chip connection.

15. The method of claim 1, wherein the mask layer is developed via wet etching.

16. A method of forming a bump comprising:
providing a wafer having a contact pad;
providing a seed layer on the contact pad;
providing a shielding layer on the seed layer;
providing a mask pattern on the shielding layer;
removing a portion of the shielding layer exposed through the mask pattern; and
forming the bump on the seed layer.

17. The method of claim 16, wherein forming the bump occurs after removing a portion of the shielding layer.

18. The method of claim 16, wherein the shielding layer includes a non-photosensitive polymer.

19. The method of claim 16, wherein the shielding layer includes a photosensitive polymer.

20. The method of claim 16, wherein the bump is superposed over a testing area of the contact pad.
